(19) United States
(12) Patent Application Publication
(10) Pub. No.: US 2026/0231399 A1
(43) Pub. Date: Aug. 6, 2026

(54) SEMICONDUCTOR PILLAR LANDING AREA

(71) Applicant: Micron Technology, Inc., Boise, ID (US)

(72) Inventors: Vinay NAIR, Boise, ID (US); Protyush SAHU, Boise, ID (US); Sutharsan KETHARANATHAN, Boise, ID (US); Silvia BORSARI, Boise, ID (US)

(21) Appl. No.: 19/407,575

(22) Filed: Dec. 3, 2025

Related U.S. Application Data
(60) Provisional application No. 63/752,192, filed on Jan. 31, 2025.

(51) Int. Cl. H10B 12/00; H10B 53/10; H10B 53/40; H10W 20/40; H10W 20/41

(52) U.S. Cl. CPC H10B 12/482; H10B 12/02; H10B 12/485; H10B 53/10; H10B 53/40; H10W 20/435; H10W 20/498

(57) ABSTRACT

Implementations described herein relate to various structures, integrated assemblies, and memory devices. In some implementations, an integrated assembly may include a first semiconductor pillar and a second semiconductor pillar extending vertically from a substrate. The integrated assembly may further include a first epitaxial structure extending vertically from the first semiconductor pillar and a second epitaxial structure extending vertically from the second semiconductor pillar, where the first epitaxial structure is separated from the second epitaxial structure by a gap. The integrated assembly may further include a nitride layer over the first epitaxial structure and the second epitaxial structure, where the nitride layer includes a bridge portion extending between a side portion of the first epitaxial structure and a side portion of the second epitaxial structure.

### CROSS-REFERENCE TO RELATED APPLICATION

This Patent Application claims priority to U.S. Provisional Patent Application No. 63/752,192, filed on January 31, 2025, entitled “IMPROVED SEMICONDUCTOR PILLAR LANDING AREA,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to improved semiconductor pillar landing area.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a diagrammatic view of an example memory device.

FIG. 2 is a circuit diagram of an example memory cell.

FIG. 3 is a diagrammatic view of an example structure described herein. FIG. 3 includes a top-down view of the structure.

FIG. 4 is a diagrammatic view of an example structure described herein. FIG. 4 includes cross-sectional views of the structure.

FIGS. 5A through 5I are diagrammatic views showing formation of the structure at example process stages of an example process of forming the structure.

FIG. 6 is a cross-sectional diagrammatic view of an example structure described herein.

FIG. 7 is a flowchart of an example method of forming an integrated assembly or memory device having an improved semiconductor pillar landing area.

### DETAILED DESCRIPTION

Manufacturing processes for memory devices, such as DRAM, may include forming an array of semiconductor pillars. The array may include a first semiconductor pillar configured as a cell contact pillar and may couple to a capacitor of a memory cell using a cell contact. The array may also include a second semiconductor pillar configured as a bit contact pillar and may couple to a digit line using a bit contact between the digit line and the bit contact pillar. The bit contact and the cell contact may form respective terminals of a transistor of the memory cell. In some examples, a process to form the cell contact may include depositing a sacrificial material, such as carbon, over the array of semiconductor pillars. The process may further include patterning the sacrificial material to form an array of sacrificial pillars over respective cell contact pillars. In some examples, forming the sacrificial pillars on the cell contact pillars may be referred to as “landing” the sacrificial pillars on respective landing areas (e.g., respective upper surfaces) of the cell contact pillars. Subsequent processing steps may include forming a dielectric material between the sacrificial pillars and exhuming the remaining sacrificial material of the sacrificial pillars to form an array of cavities in the dielectric material. Semiconductor material may be deposited to fill the array of cavities and form the cell contacts.

However, patterning the sacrificial material may include a relatively high-aspect ratio etching process. Such an etching process may fail to remove a portion of the sacrificial material between sacrificial pillars, which may result in electrical shorts between cell contacts. For example, the semiconductor material may be deposited in voids left by exhuming the sacrificial material, thus electrically coupling (e.g., shorting) adjacent cell contacts. Further, patterning the sacrificial material may result in a misalignment between the sacrificial pillars and the cell contact pillars, which may result in poor electrical connection (e.g., high resistance and/or isolation) between the cell contact and the cell contact pillar. This poor electrical connection may impede or prevent the flow of signals between the cell contact and the cell contact pillar, and thus may degrade performance of the memory device.

Some implementations described herein enable improved landing area for semiconductor pillars. For example, a manufacturing process may include forming one or more semiconductor pillars, including one or more cell contact pillars. The process may further include forming portions of a memory array, such as one or more access lines extending in a first horizontal direction and one or more digit lines extending in a second horizontal direction. Dielectric material may extend between the digit lines, and may cover upper surfaces of the one or more cell contact pillars.

The manufacturing process may include removing a portion of the dielectric material to expose the upper surfaces of the one or more cell contact pillars. The process may further include selectively depositing semiconductor material on the upper surfaces of the one or more cell contact pillars (e.g., using an epitaxial deposition process) to form one or more epitaxial structures extending vertically from respective cell contact pillars. The process may further include depositing a nitride layer over the one or more epitaxial structures, which may form one or more void regions between adjacent epitaxial structures. Subsequent manufacturing steps may include removing portions of the nitride layer to expose the one or more epitaxial structures, and forming one or more cell contacts on respective epitaxial structures.

As a result, by epitaxially growing semiconductor material from upper surfaces of the cell contact pillars, the landing area of the cell contact pillars may be increased. This arrangement may increase the active area of a cell contact (e.g., the size of the interface between the cell contact pillar and the cell contact), which may reduce resistance between the cell contact and the cell contact pillar. Additionally, the increased landing area of the cell contact pillar may reduce the likelihood of manufacturing defects associated with forming the cell contact.

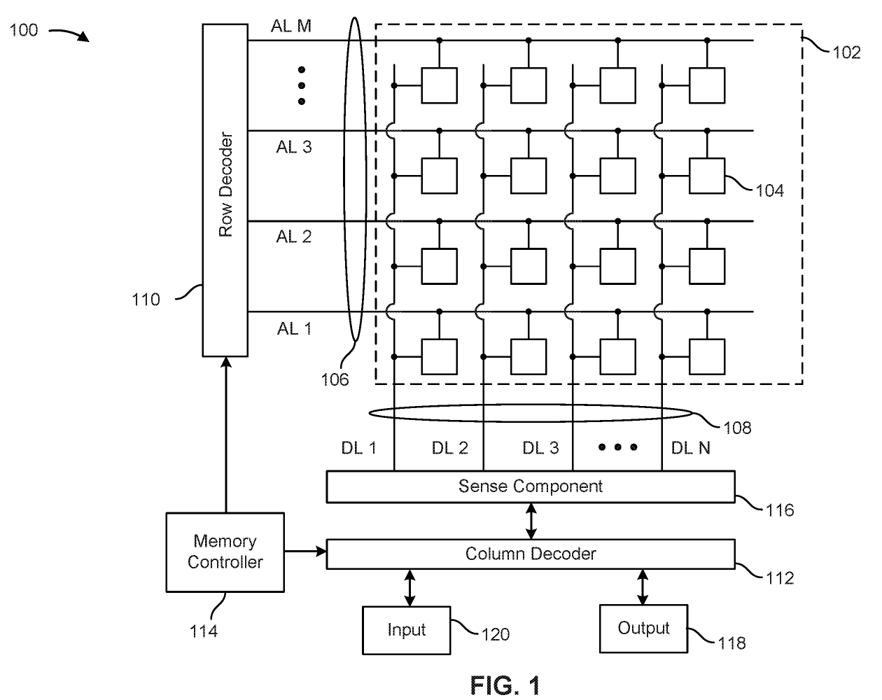

FIG. 1 is a diagrammatic view of an example memory device 100. The memory device 100 may include a memory array 102 that includes multiple memory cells 104. A memory cell 104 is programmable or configurable into a data state of multiple data states (e.g., two or more data states). For example, a memory cell 104 may be set to a particular data state at a particular time, and the memory cell 104 may be set to another data state at another time. A data state may correspond to a value stored by the memory cell 104. The value may be a binary value, such as a binary 0 or a binary 1, or may be a fractional value, such as 0.5, 1.5, or the like. A memory cell 104 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 104 by activating or selecting the appropriate access line 106 (shown as access lines AL 1 through AL M) and digit line 108 (shown as digit lines DL 1 through DL N). An access line 106 may also be referred to as a “row line” or a “word line,” and a digit line 108 may also be referred to a “column line” or a “bit line.” Activating or selecting an access line 106 or a digit line 108 may include applying a voltage to the respective line. An access line 106 and/or a digit line 108 may comprise, consist of, or consist essentially of a conductive material, such as a metal (e.g., copper, aluminum, gold, titanium, or tungsten) and/or a metal alloy, among other examples. In FIG. 1, each row of memory cells 104 is connected to a single access line 106, and each column of memory cells 104 is connected to a single digit line 108. By activating one access line 106 and one digit line 108 (e.g., applying a voltage to the access line 106 and digit line 108), a single memory cell 104 may be accessed at (e.g., is accessible via) the intersection of the access line 106 and the digit line 108. The intersection of the access line 106 and the digit line 108 may be called an “address” of a memory cell 104.

In some implementations, the logic storing device of a memory cell 104, such as a capacitor, may be electrically isolated from a corresponding digit line 108 by a selection component, such as a transistor. The access line 106 may be connected to and may control the selection component. For example, the selection component may be a transistor, and the access line 106 may be connected to the gate of the transistor. Activating the access line 106 results in an electrical connection or closed circuit between the capacitor of a memory cell 104 and a corresponding digit line 108. The digit line 108 may then be accessed (e.g., is accessible) to either read from or write to the memory cell 104.

A row decoder 110 and a column decoder 112 may control access to memory cells 104. For example, the row decoder 110 may receive a row address from a memory controller 114 and may activate the appropriate access line 106 based on the received row address. Similarly, the column decoder 112 may receive a column address from the memory controller 114 and may activate the appropriate digit line 108 based on the column address.

Upon accessing a memory cell 104, the memory cell 104 may be read (e.g., sensed) by a sense component 116 to determine the stored data state of the memory cell 104. For example, after accessing the memory cell 104, the capacitor of the memory cell 104 may discharge onto its corresponding digit line 108. Discharging the capacitor may be based on biasing, or applying a voltage, to the capacitor. The discharging may induce a change in the voltage of the digit line 108, which the sense component 116 may compare to a reference voltage (not shown) to determine the stored data state of the memory cell 104. For example, if the digit line 108 has a higher voltage than the reference voltage, then the sense component 116 may determine that the stored data state of the memory cell 104 corresponds to a first value, such as a binary 1. Conversely, if the digit line 108 has a lower voltage than the reference voltage, then the sense component 116 may determine that the stored data state of the memory cell 104 corresponds to a second value, such as a binary 0. The detected data state of the memory cell 104 may then be output (e.g., via the column decoder 112) to an output component 118 (e.g., a data buffer). A memory cell 104 may be written (e.g., set) by activating the appropriate access line 106 and digit line 108. The column decoder 112 may receive data, such as input from input component 120, to be written to one or more memory cells 104. A memory cell 104 may be written by applying a voltage across the capacitor of the memory cell 104.

The memory controller 114 may control the operation (e.g., read, write, re-write, refresh, and/or recovery) of the memory cells 104 via the row decoder 110, the column decoder 112, and/or the sense component 116. The memory controller 114 may generate row address signals and column address signals to activate the desired access line 106 and digit line 108. The memory controller 114 may also generate and control various voltages used during the operation of the memory array 102.

In some implementations, the memory device 100 may include one or more semiconductor pillars, such as one or more cell contact pillars and/or one or more bit contact pillars. A cell contact pillar and bit contact pillar may act as a transistor to selectively couple the capacitor of a memory cell to a digit line 108. As described in greater detail elsewhere herein, a cell contact pillar may include an epitaxial structure extending from an upper surface of the cell contact pillar. This epitaxial structure may provide an improved landing area for the cell contact, such as by reducing the resistance thereof and/or reducing the likelihood of manufacturing defects associated with manufacturing the memory device 100.

In some implementations, the memory device 100 includes the structure 400 and/or an integrated assembly that includes the structure 400. For example, the memory array 102 may include the structure 400 and/or an integrated assembly that includes the structure 400. Additionally, or alternatively, the memory cell 104 may include a memory cell described elsewhere herein.

As indicated above, FIG. 1 is provided as an example. Other examples may differ from what is described with respect to FIG. 1.

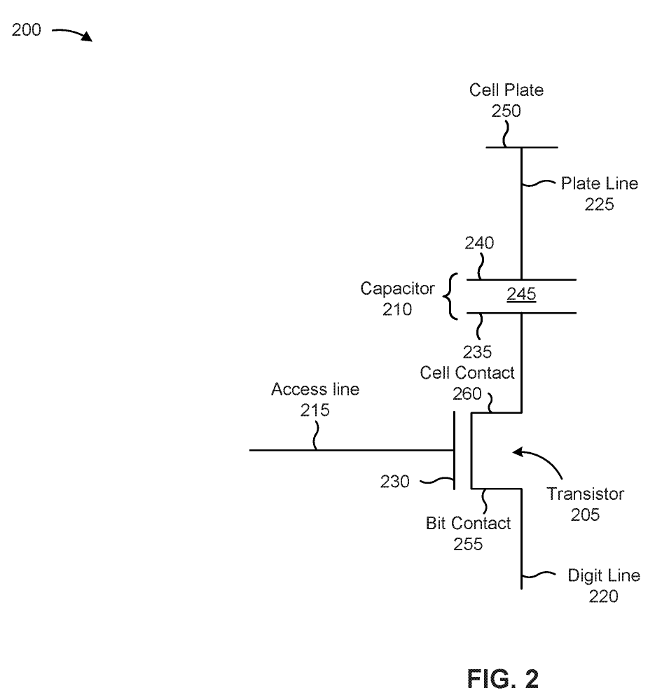

FIG. 2 is a circuit diagram of an example memory cell 200. In some implementations, the memory cell 200 is a ferroelectric memory cell. Alternatively, the memory cell 200 may be a linear dielectric memory cell or a paraelectric memory cell. As shown in FIG. 2, the memory cell 200 may include a transistor 205 (or another type of selection circuit) and a capacitor 210. The memory cell 200 may be accessed (e.g., written to, read from, and/or erased) using signals on a combination of lines that are coupled to the memory cell 200, shown as an access line 215 (sometimes called a “word line”), a digit line 220 (sometimes called a “bit line”), and a plate line 225.

The transistor 205 (sometimes called an access transistor) may include a gate 230. The capacitor 210 includes a bottom electrode 235 and a top electrode 240 separated by an insulator 245. In some implementations, the capacitor is a ferroelectric capacitor, and the insulator 245 is a ferroelectric insulator that comprises, consists of, or consists essentially of ferroelectric material. Alternatively, the capacitor may be a linear dielectric capacitor, and the insulator 245 may be a linear dielectric insulator that comprises, consists of, or consists essentially of linear dielectric material. Alternatively, the capacitor may be a paraelectric capacitor, and the insulator 245 may be a paraelectric insulator that comprises, consists of, or consists essentially of paraelectric material. When the access line 215 is activated (e.g., when a voltage is applied to the access line 215), the gate 230 coupled to the access line 215 may be activated. When the gate 230 is activated, the transistor 205 couples the digit line 220 to the bottom electrode 235 of the capacitor 210. A state of the memory cell 200 may then be written or read via the digit line 220.

The top electrode 240 of the capacitor 210 may be coupled to the plate line 225 and a cell plate 250. To write to (or program) the memory cell 200, the access line 215 may be activated, and a voltage may be applied across the capacitor 210 by controlling the voltage of the top electrode 240 (via the plate line 225 and/or the cell plate 250) and/or the bottom electrode 235 (via the digit line 220).

For a ferroelectric capacitor, the applied voltage creates an electric field, and the atoms in the ferroelectric material of the insulator 245 respond to the electric field to become arranged in a particular state (e.g., a particular orientation or polarization), which is representative of a data state (e.g., a logic “0” state or a logic “1” state). In some implementations, data may be stored using the capacitor 210 by controlling a voltage difference and/or a polarity difference of the capacitor 210 (e.g., of the insulator 245 between the bottom electrode 235 and the top electrode 240). For example, a voltage of the cell plate 250 and the digit line 220 may be controlled. In some implementations, a negative polarity of the insulator 245 as compared to the cell plate 250 results in a logic “0” state being stored in the capacitor 210, and a positive polarity of the insulator 245 as compared to the cell plate 250 results in a logic “1” state being stored in the capacitor 210. For a linear dielectric capacitor or a paraelectric capacitor, the cell plate 250 may grounded, and the capacitor 210 may be charged by applying a voltage to the bottom electrode 235 via the digit line 220.

To read the memory cell 200 (e.g., a state stored by the capacitor 210), the access line 215 may be activated, and a voltage may be applied to the plate line 225. Applying a voltage to the plate line 225 may cause a change in the stored charge on the capacitor 210. The magnitude of the change in stored charge may depend on the stored state of capacitor 210 (e.g., whether the stored state is a logic “1” state or a logic “0” state). This may or may not induce a threshold change in the voltage of the digit line 220 based on the charge stored on the capacitor 210. The change in voltage or lack of change in voltage of the digit line 220 (or a magnitude of the change in voltage) may be used to determine the stored state of the capacitor 210. For example, if the change in voltage satisfies a threshold, then the read operation indicates that a first state was stored in the capacitor 210, whereas if the change in voltage does not satisfy the threshold, then the read operation determines that a second state was stored in the capacitor 210. In some cases, multiple threshold voltages may be used, such as when the capacitor is capable of storing more than two data states (e.g., for a multi-level cell, a triple-level cell, and so on).

In some implementations, the transistor 205 may include a bit contact 255, a cell contact 260, and one or more semiconductor pillars extending vertically from a semiconductor substrate. The cell contact 260 may be part of a connection between the transistor 205 and the capacitor 210. For example, the cell contact 260 may include doped semiconductor material (e.g., n-type doped semiconductor material, p-type doped semiconductor material, and/or an allowed semiconductor material, such as silicon-germanium and/or silicon carbide) coupled with a first semiconductor pillar (e.g., a cell contact pillar) of the one or more semiconductor pillars, and may form a first terminal of the transistor 205. The bit contact 255 may be part of a connection between the transistor 205 and the digit line 220. For example, the bit contact 255 may include doped semiconductor material (e.g., n-type doped semiconductor material or p-type doped semiconductor material) coupled with a second semiconductor pillar (e.g., a bit contact pillar) of the one or more semiconductor pillars and may form a second terminal of the transistor 205. Thus, the cell contact 260 may be used as the source terminal of the transistor 205, the bit contact 255 may be used as the drain terminal of the transistor 205, and the one or more semiconductor pillars may be used as a channel region of the transistor 205. As described in greater detail elsewhere herein, a cell contact pillar may include an epitaxial structure extending from an upper surface of the cell contact pillar. This epitaxial structure may provide an improved landing area for the cell contact 260, such as by reducing the resistance thereof and/or reducing the likelihood of manufacturing defects associated with manufacturing the memory cell 200.

As indicated above, FIG. 2 is provided as an example. Other examples may differ from what is described with respect to FIG. 2.

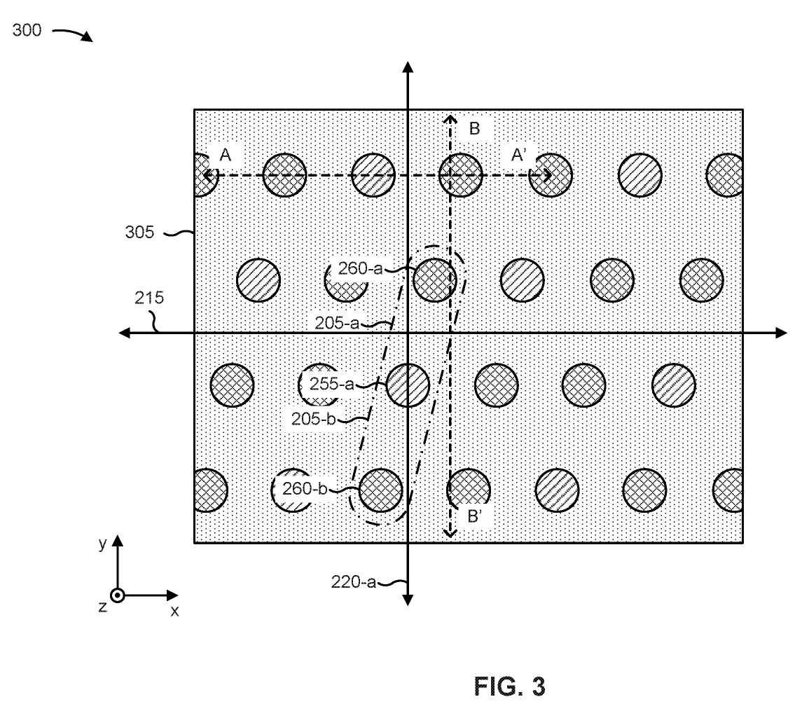

FIG. 3 is a top-down diagrammatic view of an example structure 300. The structure 300 may be part of an integrated assembly, such as a memory array, a portion of a memory array, or a memory device that includes the memory array and one or more other components (e.g., sense amplifiers, a row decoder, a column decoder, a row address buffer, a column address buffer, one or more data buffers, one or more clocks, one or more counters, and/or a memory controller). The structure 300 may be associated with a manufacturing step of manufacturing a memory device. Subsequent manufacturing steps may alter the structure 300, such as by forming additional layers, removing one or more layers of the structure 300, and/or modifying one or more components of the structure 300, among other examples.

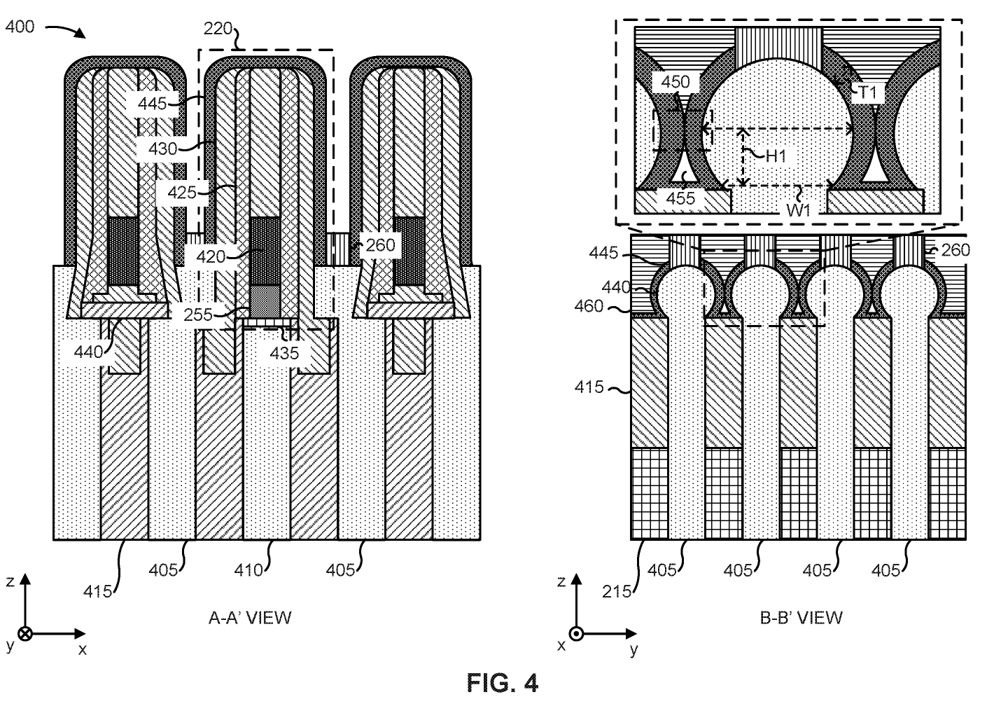

The structure 300 may be part of or may include aspects of a memory array 102. For example, the structure 300 may include one or more bit contacts 255 and one or more cell contacts 260 arranged in a grid-like structure. A cell contact 260 may couple to an upper surface of a first semiconductor pillar (e.g., a cell contact pillar, as described in greater detail in connection to FIG. 4A) extending vertically from a semiconductor substrate. A bit contact 255 may couple to an upper surface of a second semiconductor pillar (e.g., a cell contact pillar, as described in greater detail in connection to FIG. 4A) extending vertically from a semiconductor substrate. In some examples, the structure 300 may include a dielectric material 305 extending between the one or more bit contacts 255 and the one or more cell contacts 260, which may provide structural support to the structure 300 and/or may isolate the one or more bit contacts 255 and the one or more cell contacts 260.

The structure 300 may include one or more access lines 215 extending in a first horizontal direction (e.g., the x-direction). In some cases, the first horizontal direction may be based on a crystal orientation of the semiconductor substrate. For example, the first horizontal direction may correspond to or be based on the (100) direction, the (110) direction, and/or the (111) direction of the semiconductor substrate, among other examples. The one or more access lines 215 may be positioned beneath the bit contacts 255 and the cell contacts 260 (e.g., between a cell contact 260 and the semiconductor substrate), as described in greater detail in connection with FIG. 4.

In some examples, the structure 300 may include, or subsequent manufacturing operations may form, one or more digit lines 220 extending in a second horizontal direction (e.g., a digit line direction) approximately perpendicular to the first horizontal direction. As described in greater detail in connection with FIG. 4, a digit line 220 may include a conductive portion extending in the second horizontal direction and one or more dielectric layers covering one or more sidewalls and/or upper surfaces of the conductive portion.

The bit contacts 255, the cell contacts 260, and the access lines 215 may form one or more transistors 205. For example, a cell contact 260 may act as a source terminal of a transistor 205, a bit contact 255 may act as a drain terminal of the transistor 205, and an access line 215 may act as the gate of the transistor 205. Accordingly, activating the access line 215 may allow current to flow from a capacitor 210 coupled to the cell contact 260 to a digit line 220 coupled to the bit contact 255-a. In some examples, a bit contact 255 may be shared between pairs of transistors 205. For example, a first transistor 205-a may include a cell contact 260-a and a bit contact 255-a. A second transistor 205-b may include a cell contact 260-b and the bit contact 255-a.

As described in greater detail elsewhere herein, a manufacturing process for a memory device that includes the structure 300 may support forming one or more epitaxial structures on upper surfaces of the cell contact pillars. These epitaxial structures may provide an increased landing area for respective cell contacts 260, which may improve the electrical connection (e.g., may reduce the resistance) between a cell contact 260 and an associated cell contact pillar. Further, a larger landing area for a cell contact 260 may decrease the likelihood of manufacturing defects associated with forming the structure 300.

As indicated above, FIG. 3 is provided as an example. Other examples may differ from what is described with regard to FIG. 3.

FIG. 4 is a diagrammatic view of an example structure 400. The structure 400 may be part of an integrated assembly, such as a memory array, a portion of a memory array, or a memory device that includes the memory array and one or more other components (e.g., sense amplifiers, a row decoder, a column decoder, a row address buffer, a column address buffer, one or more data buffers, one or more clocks, one or more counters, and/or a memory controller). For example, the structure 400 may be part of or may include aspects of a memory array 102, a memory cell 104, and/or a memory cell 200. The structure 400 may be associated with a manufacturing step of manufacturing a memory device. Subsequent manufacturing steps may alter the structure 400, such as by forming additional layers, removing one or more layers of the structure 400, and/or modifying one or more components of the structure 400, among other examples. FIG. 4 illustrates a cross-sectional view of the structure 400 along the plane A-A’ illustrated in connection with FIG. 3 and a cross-sectional view of the structure 400 along the plane B-B’ illustrated in connection with FIG. 3.

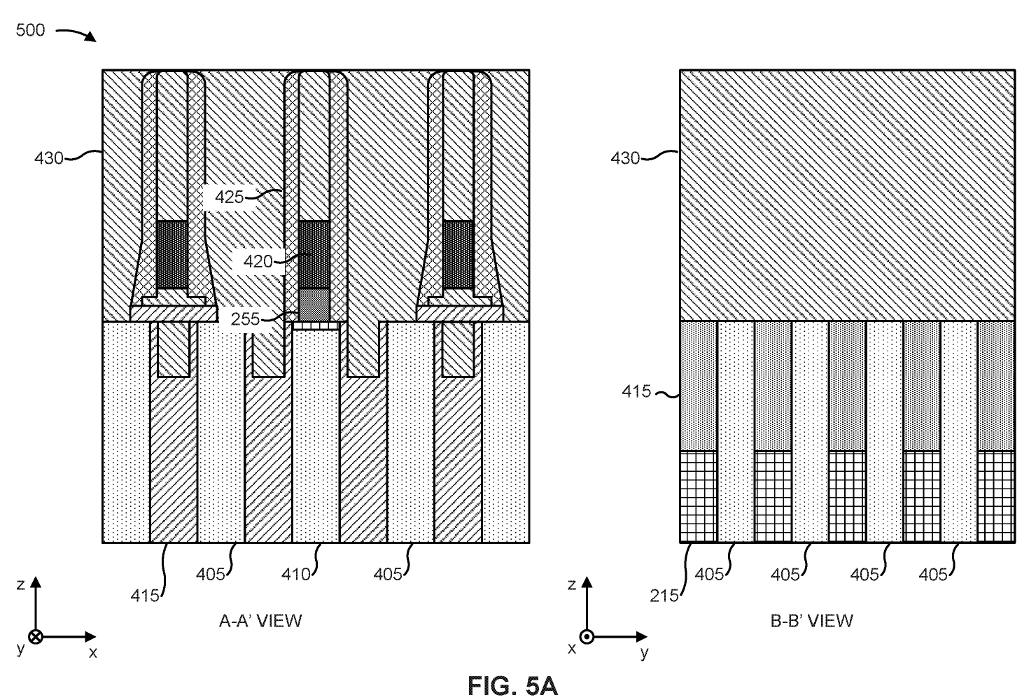

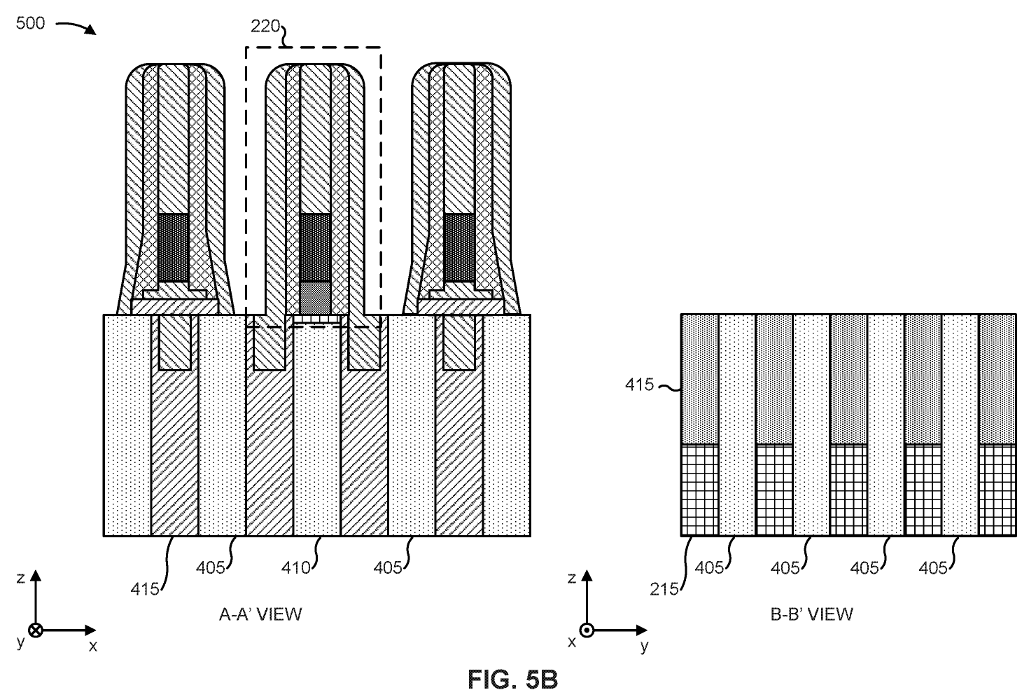

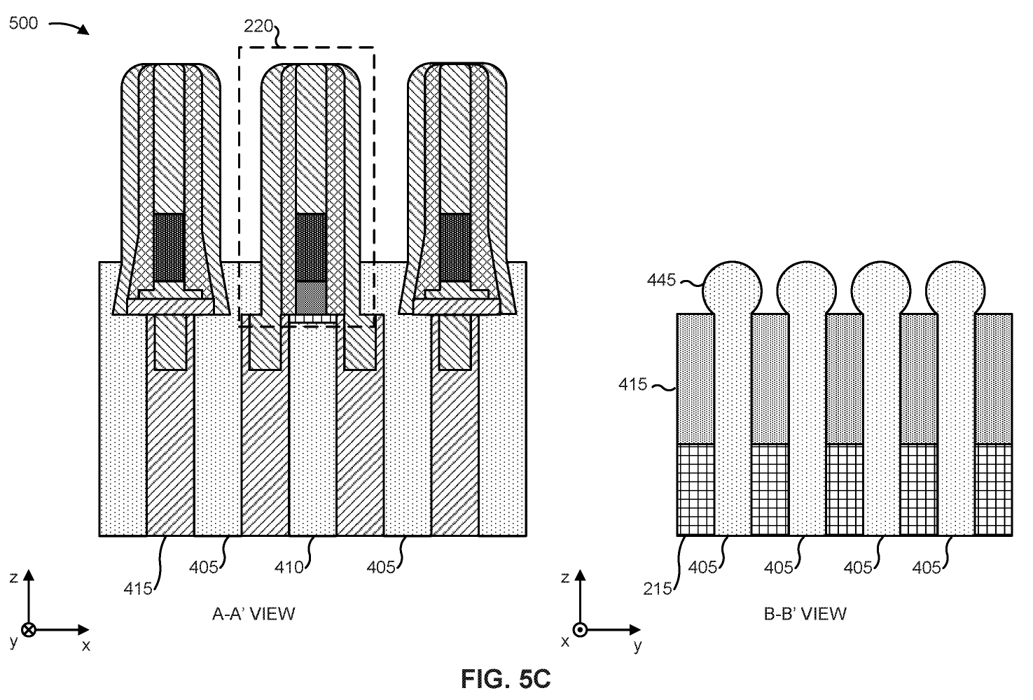

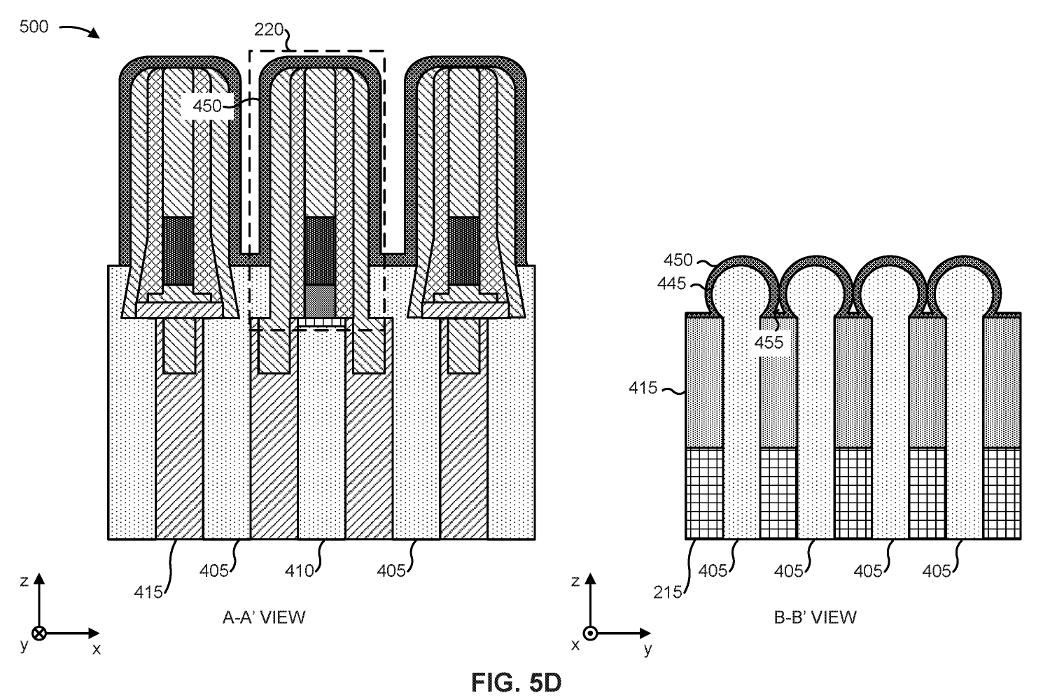

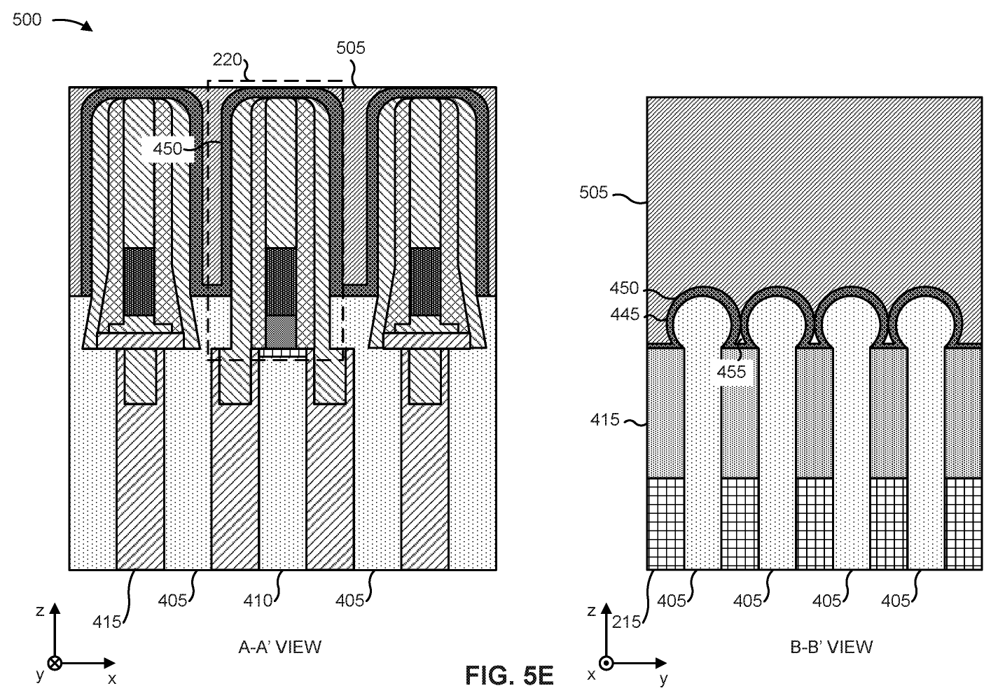

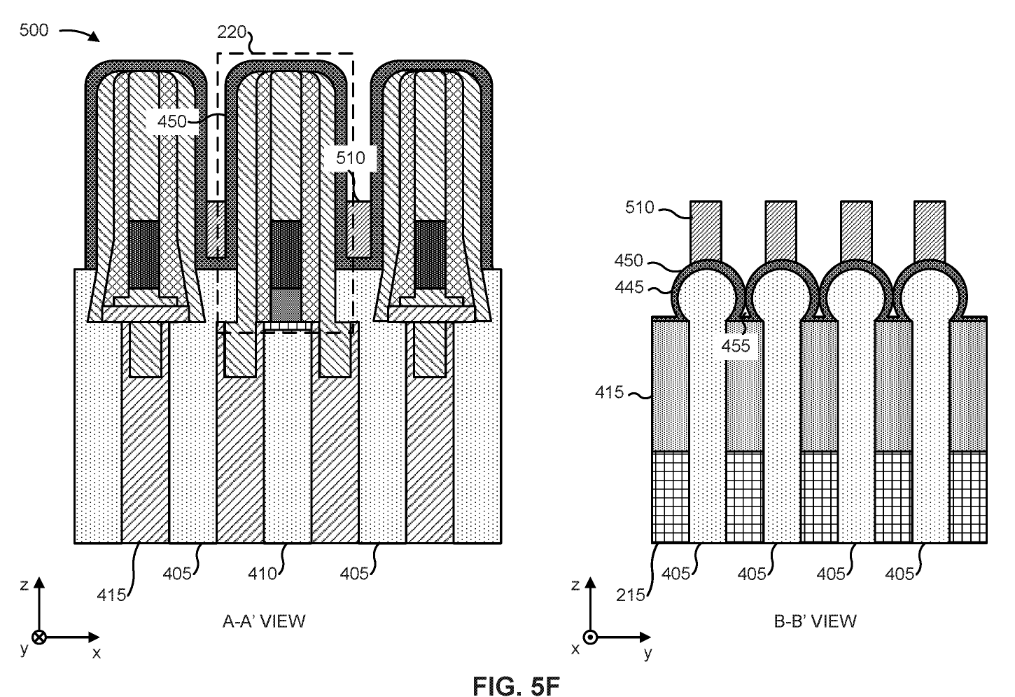

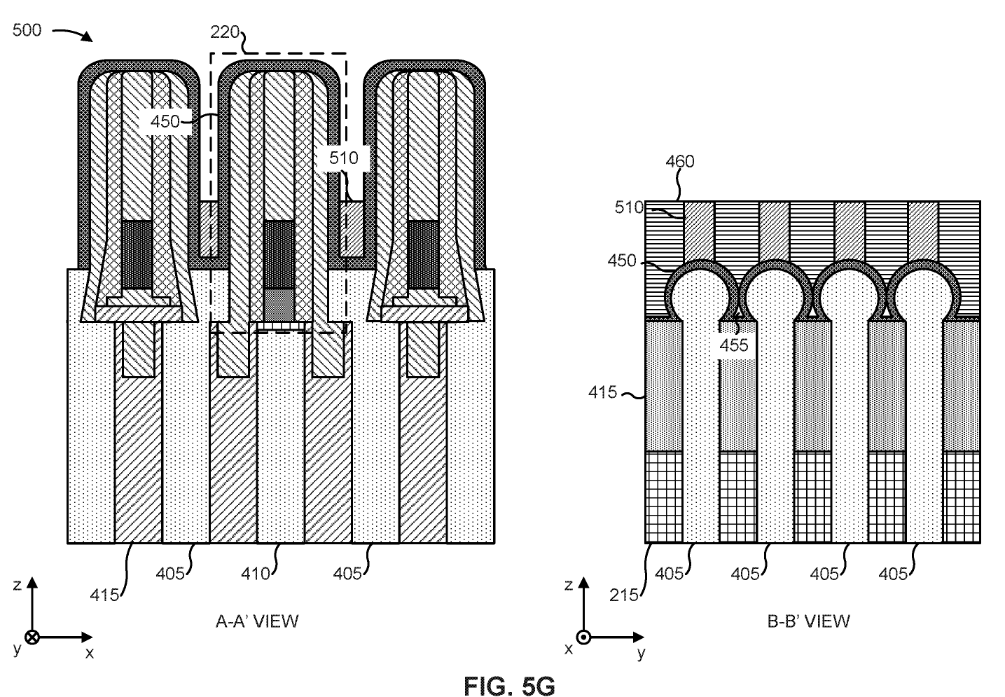

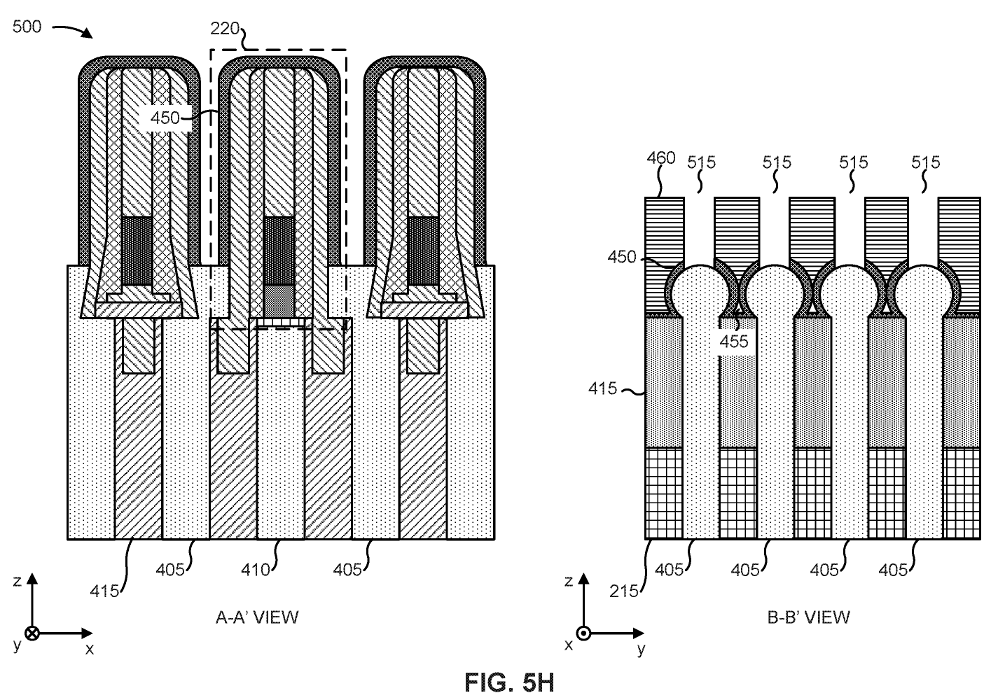

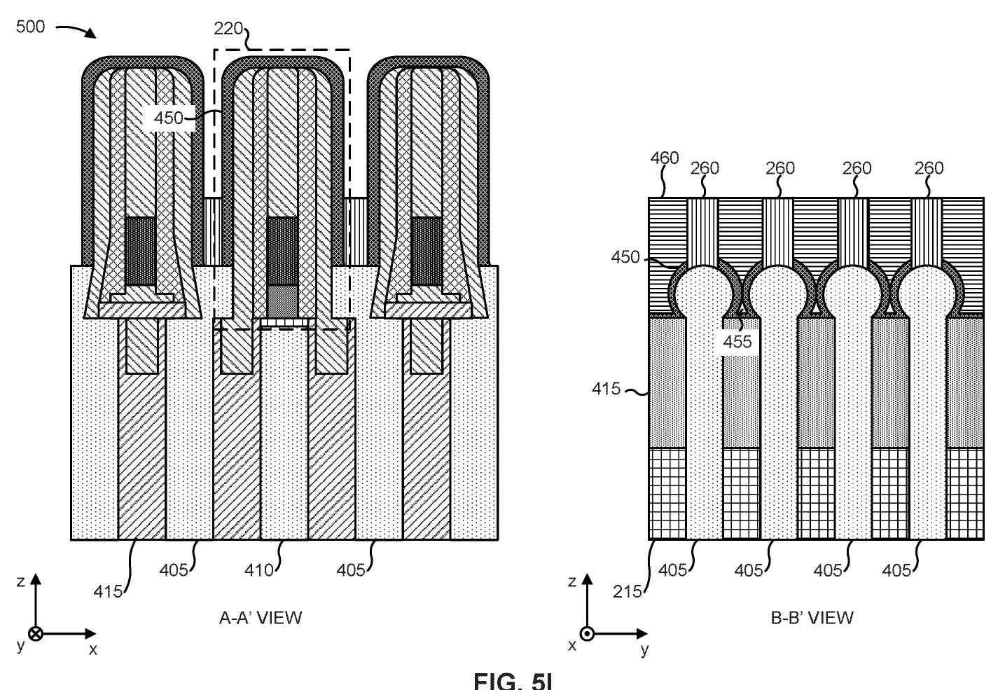

The structure 400 may include one or more components of one or more transistors 205. For example, the structure 400 may include an array of one or more semiconductor pillars. A semiconductor pillar (e.g., each semiconductor pillar) may extend vertically (e.g., in the z-direction) from a semiconductor substrate. The semiconductor substrate may be a bulk silicon substrate, a bulk silicon-germanium substrate, and/or a bulk silicon-carbon substrate, among other examples. In some examples, the semiconductor substrate may be doped (e.g., lightly doped) with a p-type or an n-type impurity. As described in greater detail in connection with FIG. 5A, the semiconductor pillars may be formed by etching one or more trenches in the semiconductor substrate.

The array of one or more semiconductor pillars may include one or more cell contact pillars 405 and one or more bit contact pillars 410. The one or more cell contact pillars 405 and the one or more bit contact pillars 410 may be arranged in a grid structure and may be positioned under one or more cell contacts 260 and one or more bit contacts 255, respectively, as described in greater detail in connection with FIG. 3. A bit contact pillar 410 may be configured to couple to a digit line 220 (e.g., using a bit contact 255), and a cell contact pillar 405 may be configured to couple to a capacitor of a memory cell (e.g., using a cell contact 260). A bit contact pillar 410 may form part of a first terminal (e.g., a drain) and/or a channel of one or more transistors 205. A cell contact pillar 405 may form part of a second terminal (e.g., a drain) and/or a channel of one or more transistors.

The structure 400 may include one or more shallow-trench isolation (STI) regions between adjacent semiconductor pillars. An STI region may include one or more layers of dielectric material. For example, the one or more layers of dielectric material may include a gate oxide material conformally deposited to abut sidewalls of a bit contact pillar 410, a cell contact pillar 405, and/or a surface of the semiconductor substrate within the STI region. The gate oxide material may be a dielectric material, such as silicon-oxide or other insulating material. The gate oxide material may insulate a gate of a transistor from the bit contact pillar 410, the cell contact pillar 405, and/or the surface of the semiconductor substrate within the STI region.

The structure 400 may include one or more access lines 215 extending in a first horizontal direction (e.g., in the x-direction). An access line 215 may act as a gate structure for the transistor. An access line 215 may include an electrical conductor and may comprise, consist of, or consist essentially of conductive material. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), among other examples.

In some examples, the structure 400 may include a dielectric material 415, such as silicon oxide and/or silicon nitride, among other examples, in the STI region. The dielectric material 415 may be an insulative material used to isolate adjacent semiconductor pillars and/or provide mechanical support to the structure 400 during manufacturing operations. In some implementations, the access line 215 and the dielectric material 415 may form a gate structure for a transistor. For example, the gate structure may include a conductive portion (e.g., a metal portion of the access line 215) and a cap portion (e.g., the dielectric material 415) on the conductive portion. In such an example, the gate oxide material may be between the bit contact pillar 410 and the gate structure. The gate oxide material may cover a side surface (e.g., a sidewall) of the conductive portion. Additionally, the gate oxide material may cover a lower side surface (e.g., a lower sidewall) of the cap portion without covering an upper side surface (e.g., an upper sidewall) of the cap portion.

The structure 400 may include one or more digit lines 220 extending in a second horizontal direction (e.g., in the y-direction). A digit line 220 may include an electrical conductor which may comprise, consist of, or consist essentially of conductive material 420. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), among other examples. Additionally, a digit line 220 may include one or more layers of dielectric material, such as a dielectric material 425 and a dielectric material 430. In some examples, the dielectric material 425 may be configured to have a lower dielectric constant compared to the dielectric material 430. For example, the dielectric material 425 may be a low-k dielectric material, such as silicon oxycarbide, and the dielectric material 430 may be a nitride material, such as silicon nitride. The one or more layers of dielectric material may cover one or more sidewalls and/or an upper surface of the conductive material 420, as illustrated in FIG. 4.

A digit line 220 may couple to a bit contact pillar 410 using a bit contact 255. The bit contact 255 may be below the conductive material 420. In some examples, the bit contact 255 may be in contact with a lower surface of the conductive material 420. Alternatively, the digit line 220 and/or the bit contact 255 may include one or more layers 435 (e.g., conductive layers) between the lower surface of the conductive material 420 and an upper surface of the bit contact 255.

The structure 400 may include one or more epitaxial structures 440 on respective cell contact pillars 405. An epitaxial structure 440 may extend vertically from an upper surface of a respective cell contact pillar 405. As described in greater detail in connection with FIG. 5C, an epitaxial structure 440 may be grown using an epitaxial deposition process. The epitaxial structure 440 may be a semiconductor and may comprise, consist of, or consist essentially of semiconductive material. The semiconductive material may comprise, consist of, or consist essentially of silicon (e.g., epitaxial silicon), among other examples. In some implementations, the epitaxial structure 440 may be a same material as or a different material than the cell contact pillar 405.

The epitaxial structure 440 may have a rounded and/or an oblique profile in the vertical direction (e.g., along the z-direction). For example, a lower width W1 of the epitaxial structure 440 (e.g., a width measured at or near the interface with the cell contact pillar 405) may be less than a central width W2 of the epitaxial structure (e.g., a width measured at a height H1 above the interface with the cell contact pillar). The rounder profile may form lateral extensions and/or overhangs of the epitaxial structure. These lateral overhangs may extend beyond the upper surface of the cell contact pillar 405 in a horizontal direction (e.g., the x-direction and/or the y-direction).

The structure 400 may include a nitride layer 445. The nitride layer 445 may be above the one or more epitaxial structures 440 on the respective cell contact pillars 405. As described in greater detail in connection with FIG. 5D, the nitride layer 445 may be conformally deposited to cover the one or more epitaxial structures 440, one or more sidewall portions of the digit lines 220, and/or respective upper surfaces of the dielectric material 415. Depositing the nitride layer 445 may result in a thickness T1 of the nitride layer 445. The nitride layer 445 may be an electrical insulator and may comprise, consist of, or consist essentially of insulative material. The insulative material may comprise, consist of, or consist essentially of silicon nitride, among other examples.

The thickness T1 of the nitride layer 445 may be sufficiently large to cause a first portion of the nitride layer 445 on a sidewall of a first epitaxial structure 440 to contact a second portion of the nitride layer 445 on a sidewall of a second epitaxial structure 440. Such an arrangement may form one or more bridge portions 450 extending between respective pairs of adjacent epitaxial structures 440. A bridge portion 450 may span across side surfaces of the adjacent epitaxial structures 440, such that the nitride layer 445 may be continuous across the one or more epitaxial structures 440. The one or more bridge portions 450 may act as a sealing layer to create one or more void regions 455. A void region 455 may be a gap (e.g., an air gap) between a lower surface of a bridge portion 450 and the nitride layer 445 on an upper surface of the dielectric material 415.

The structure 400 may include one or more cell contacts 260 coupled to respective epitaxial structures 440. The one or more cell contacts may be within a layer of dielectric material 460. The one or more epitaxial structures 440 may increase the landing area of the one or more cell contact pillars 405 for the one or more cell contacts 260. This arrangement may increase the active area of a cell contact 260 (e.g., the size of the interface between a cell contact pillar 405 and a cell contact 260), which may reduce resistance between the cell contact 260 and the cell contact pillar 405. Additionally, the increased landing area of the cell contact pillar 405 may reduce the likelihood of manufacturing defects associated with forming the cell contact 260.

Each of the illustrated axes (e.g., in the x-direction, the y-direction, and the z-direction) are substantially perpendicular to the other two axes. In other words, the x-direction is substantially perpendicular to the y-direction and the z-direction, the y-direction is substantially perpendicular to the x-direction and the z-direction, and the z-direction is substantially perpendicular to the x-direction and the y-direction. In some cases, a single reference number is shown to refer to a surface, or fewer than all instances of a part may be labeled with all surfaces of that part. All instances of the part may include associated surfaces of that part despite not every surface being labeled.

As indicated above, FIG. 4 is provided as an example. Other examples may differ from what is described with regard to FIG. 4.

FIGS. 5A through 5I are diagrammatic views showing formation of the structure 400 at example process stages of an example process 500 of forming the structure 400. In some implementations, the example process described below in connection with FIGS. 5A through 5I may correspond to the method 700 and/or one or more blocks of the method 700. However, the process described below is an example, and other example processes may be used to form the structure 400, an integrated assembly that includes the structure 400, and/or one or more parts of the structure 400 and/or the integrated assembly.

FIG. 5A illustrates an example starting stage of forming the structure 400. Additional processing steps may be performed prior to and/or in addition to the process 500. For example, the process 500 may include forming the one or more cell contact pillars 405 extending vertically from a substrate, and may include forming the one or more bit contact pillars 410 extending vertically from the substrate. Forming the cell contact pillars 405 and the bit contact pillars 410 may include etching one or more trenches (e.g., one or more STI regions) in a semiconductor substrate to define the cell contact pillars 405 and the bit contact pillars 410.

The process 500 may include forming the access lines 215. Forming the access lines 215 may include depositing a gate oxide material onto the surfaces and/or sidewalls of the one or more trenches etched into the semiconductor substrate, providing necessary electrical insulation. A conductive material, such as tungsten and/or titanium, may be deposited on the gate oxide material, for example using chemical vapor deposition (CVD) and/or physical vapor deposition (PVD). The dielectric material 415 may be deposited over the conductive material to fill the one or more trenches. In some examples, the process 500 may include a planarization step, such as a chemical-mechanical planarization (CMP) process to smooth the upper surface of the cell contact pillars 405, the bit contact pillars 410, and/or the dielectric material 415.

The process 500 may include forming the digit lines 220. Forming the digit lines 220 may include forming one or more bit contacts 255 to couple to respective upper surfaces of bit contact pillars 410. Forming a digit line 220 may include forming the conductive material 420 (a conductive portion) over the one or more bit contacts 255 to form a set of elongated conductive lines. Forming the digit line 220 may further include forming the dielectric material 425 and the dielectric material 430 (e.g., one or more dielectric layers) to cover upper and/or side surfaces of the conductive material 420. As shown in FIG. 5A, the dielectric material 430 may cover upper surfaces of the cell contact pillars 405.

As shown in FIG. 5B, the process 500 may include removing one or more portions of the dielectric material 430 to form one or more trenches. Forming the one or more trenches may include performing an etching process, such as reactive ion etching (RIE) and/or plasma etching, to selectively remove the exposed portions of the dielectric material 430. Removing the portions of the dielectric material 430 may expose the upper surfaces of the cell contact pillars 405.

For example, the process 500 may include performing a patterning process to define the areas of the dielectric material 430 to be removed. A photoresist material may be deposited onto the surface of the dielectric material 430 and exposed to a patterned light source to create a pattern in the photoresist material. A developer may be used to remove portions of the photoresist material and reveal the underlying dielectric material 430 in the areas where the one or more trenches are to be formed.

As shown in FIG. 5C, the process 500 may include forming the one or more epitaxial structures 440. Forming the one or more epitaxial structures 440 may include an epitaxial deposition process. The epitaxial deposition process may grow semiconductor material outwardly (e.g., vertically and/or horizontally) from exposed upper surfaces of the cell contact pillars 405. During the epitaxial growth, the semiconductor material may be deposited layer-by-layer, and may replicate the crystal orientation of the cell contact pillars 405. This growth may occur both vertically and laterally, which may increase the landing area of the cell contact pillars 405.

One or more parameters of the epitaxial deposition process may be configured to prevent adjacent epitaxial structures 440 from merging. For example, the growth rate may be controlled by adjusting the temperature, pressure, and/or gas flow rates within a reaction chamber. In some examples, lower temperatures and/or reduced gas flow rates may slow the deposition process and allow for control over the lateral growth of the epitaxial structures 440. Additionally, the composition of the process gases of the epitaxial deposition process may be configured, such as by using a mixture of silicon-containing gases such as silane (SiH4) and/or dichlorosilane (DCS) with carrier gases like hydrogen (H2) to modify the growth characteristics to favor vertical expansion over lateral spread. Such modified growth may support forming the rounded and/or oblique profile of the epitaxial structures 440.

As shown in FIG. 5D, the process 500 may include forming the nitride layer 445. Forming the nitride layer 445 may include depositing a dielectric material (e.g., a nitride material, such as silicon nitride) to conformally cover respective surfaces of the epitaxial structures 440. Depositing the nitride layer 445 may also cover the exposed surfaces of the digit lines 220 (e.g., a sidewall portion of a digit line 220). Depositing the nitride layer 445 may include performing low-pressure chemical vapor deposition (LPCVD) and/or atomic layer deposition (ALD). Depositing the nitride layer 445 may form one or more void regions 455. The one or more void regions 455 may be formed beneath the one or more bridge portions 450, and may include isolated gaps or air pockets between the epitaxial structures 440.

One or more parameters of the nitride deposition process may be configured to cause the thickness of the nitride layer 445 to be sufficient to cause nitride layers to merge and form bridge portions 450. For example, the deposition process may be controlled by carefully adjusting the flow rate of precursor gases, the temperature within the deposition chamber, and/or the deposition time. By configuring these parameters, the nitride material may be deposited to a desired thickness T1 to cause the sidewalls of nitride layer 445 on adjacent epitaxial structures 440 to come into contact and merge. This merging of the nitride layer 445 may form the bridge portions 450 to span between adjacent epitaxial structures 440.

As shown in FIG. 5E, the process 500 may include forming a sacrificial material 505, such as carbon, over the nitride layer 445. Forming the sacrificial material 505 may include depositing the sacrificial material 505 over the surface of the nitride layer 445. The sacrificial material 505 may be deposited using techniques such as CVD and/or PVD.

As shown in FIG. 5F, the process 500 may include forming one or more sacrificial pillars 510 over the epitaxial structures 440 (e.g., aligned with the epitaxial structures 440). Forming the one or more sacrificial pillars 510 may include patterning the sacrificial material 505. For example, the process 500 may include depositing a photoresist layer over the sacrificial material 505 and exposing the photoresist to patterned light to create a pattern. An etching process, such as RIE, may then be used to remove the exposed sacrificial material 505, leaving behind the sacrificial pillars 510.

As shown in FIG. 5G, the process 500 may include forming a dielectric material 460, such as a nitride and/or an oxide, over the nitride layer 445. Forming the dielectric material 460 may include depositing the dielectric material 460 to fill the spaces between the sacrificial pillars 510 and cover the nitride layer 445. The deposition process may include techniques such as CVD, PVD, and/or ALD. After deposition, a planarization step, such as CMP, may be performed to smooth the surface of the dielectric material 460.

As shown in FIG. 5H, the process 500 may include forming one or more trenches 515. Forming the one or more trenches 515 may include removing the one or more sacrificial pillars 510. For example, the sacrificial pillars 510 may be selectively removed using an oxygen plasma etching process. The one or more trenches 515 may correspond to locations where one or more cell contacts 260 will be formed.

As shown in FIG. 5I, the process 500 may include forming one or more cell contacts 260. Forming the one or more cell contacts 260 may include depositing a semiconductor material in the one or more trenches 515. For example, forming the one or more cell contacts 260 may include depositing a polysilicon material, such as by using a low-pressure chemical vapor deposition (LPCVD) process to fill the one or more trenches 515. Additionally, or alternatively, forming the one or more cell contacts 260 may include an epitaxial deposition to grow crystalline semiconductor material within the one or more trenches 515.

In some implementations, forming the one or more cell contacts 260 may include doping the semiconductor material. For example, n-type or p-type dopants, such as phosphorus or boron, may be introduced during the deposition process (in-situ doping) to modify the electrical properties of the cell contacts. Additionally, or alternatively, the doping of the semiconductor material in the cell contacts 260 may be performed after deposition using ion implantation techniques.

As indicated above, the process steps described in connection with FIGS. 5A through 5I are provided as examples. Other examples may differ from what is described with respect to FIGS. 5A through 5I. The structure shown in FIG. 5I may be equivalent to the structure 400 described elsewhere herein. In process steps above that describe forming material, such material may be formed, for example, using CVD, ALD, PVD, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

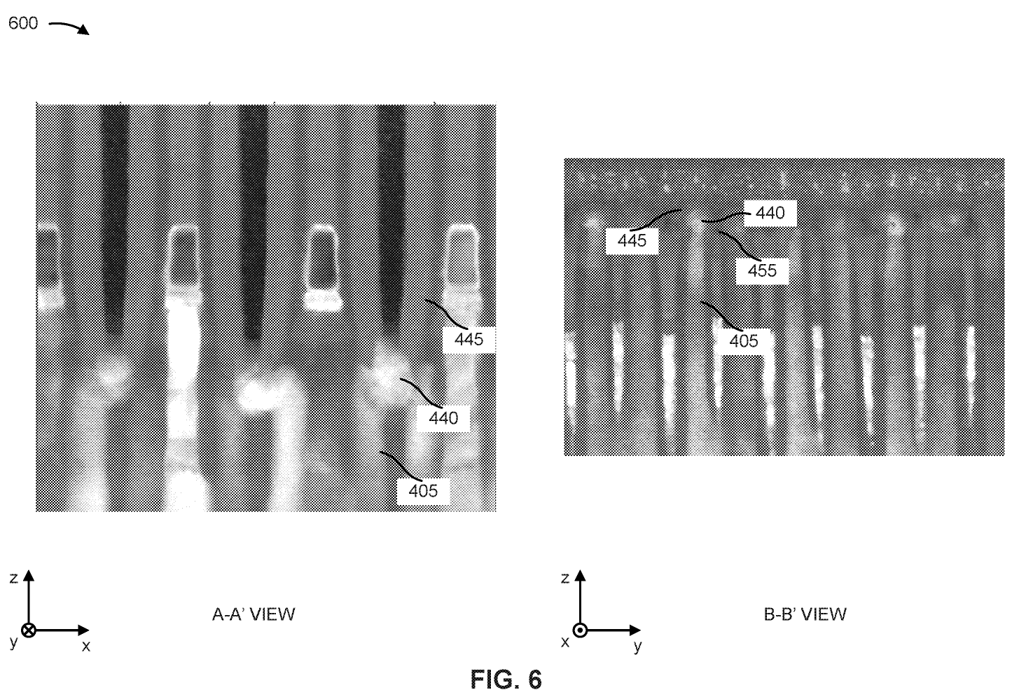

FIG. 6 is a diagrammatic view of an example structure 600. The structure 600 may represent a measured image, such as a high-resolution transmission electron microscopy (HRTEM) image, of the structure 400. FIG. 6 illustrates a cross-sectional view of the structure 600 along the plane A-A’ illustrated in connection with FIG. 3 and a cross-sectional view of the structure 600 along the plane B-B’ illustrated in connection with FIG. 3.

The structure 600 may include one or more epitaxial structures 440. As shown in FIG. 6, the one or more epitaxial structures 440 may have a rounded profile. The rounder profile may form lateral extensions and/or overhangs of the epitaxial structure. These lateral overhangs may extend beyond the upper surface of the cell contact pillar 405 in a horizontal direction (e.g., the x-direction and/or the y-direction).

The structure 600 may include a nitride layer 445. As shown in FIG. 6, the nitride layer 445 may be above the one or more epitaxial structures 440 on the respective cell contact pillars 405. The thickness of the nitride layer 445 may be sufficiently large to cause a first portion of the nitride layer 445 on a sidewall of a first epitaxial structure 440 to contact a second portion of the nitride layer 445 on a sidewall of a second epitaxial structure 440. Such an arrangement may form one or more bridge portions extending between respective pairs of adjacent epitaxial structures 440. The one or more bridge portions may act as a sealing layer to create one or more void regions 455. A void region 455 may be a gap (e.g., an air gap) below a lower surface of a bridge portion.

As indicated above, FIG. 6 is provided as an example. Other examples may differ from what is described with respect to FIG. 6.

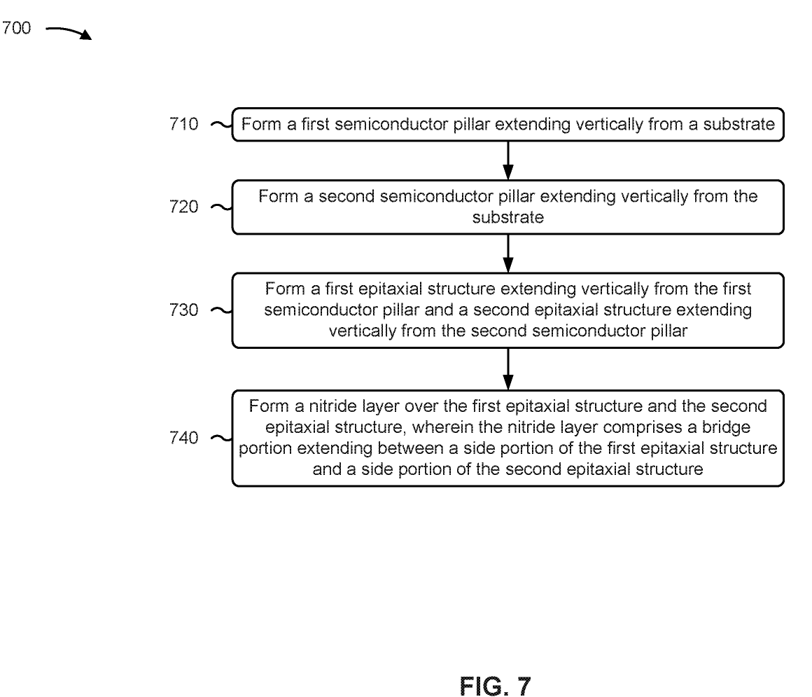

FIG. 7 is a flowchart of an example method 700 of forming an integrated assembly or memory device having improved semiconductor pillar landing area. In some implementations, one or more process blocks of FIG. 7 may be performed by various semiconductor manufacturing equipment.

As shown in FIG. 7, the method 700 may include forming a first semiconductor pillar extending vertically from a substrate (block 710). As further shown in FIG. 7, the method 700 may include forming a second semiconductor pillar extending vertically from the substrate (block 720). As further shown in FIG. 7, the method 700 may include forming a first epitaxial structure extending vertically from the first semiconductor pillar and a second epitaxial structure extending vertically from the second semiconductor pillar (block 730). As further shown in FIG. 7, the method 700 may include forming a nitride layer over the first epitaxial structure and the second epitaxial structure, where the nitride layer includes a bridge portion extending between a side portion of the first epitaxial structure and a side portion of the second epitaxial structure (block 740).

The method 700 may include additional aspects, such as any single aspect or any combination of aspects described below and/or in connection with one or more other methods described elsewhere herein.

In a first aspect, the method 700 includes forming a third semiconductor pillar extending vertically from the substrate, and forming a digit line extending in a first horizontal direction over the third semiconductor pillar, where the digit line includes a conductive portion and one or more dielectric layers covering one or more sidewalls of the conductive portion.

In a second aspect, alone or in combination with the first aspect, forming the digit line includes removing a portion of the one or more dielectric layers to form a trench exposing respective upper surfaces of the first semiconductor pillar and the second semiconductor pillar.

In a third aspect, alone or in combination with one or more of the first and second aspects, forming the first epitaxial structure and forming the second epitaxial structure includes performing an epitaxial deposition process to grow first semiconductor material on an upper surface of the first semiconductor pillar and to grow second semiconductor material on an upper surface of the second semiconductor material.

In a fourth aspect, alone or in combination with one or more of the first through third aspects, forming the nitride layer includes depositing nitride material to cover a portion of the first epitaxial structure and to cover a portion of the second epitaxial structure, where depositing the nitride material forms a void region, and where the void region is between the first epitaxial structure and the second epitaxial structure, and the void region is below the bridge portion of the nitride layer.

Although FIG. 7 shows example blocks of the method 700, in some implementations, the method 700 may include additional blocks, fewer blocks, different blocks, or differently arranged blocks than those depicted in FIG. 7. In some implementations, the method 700 may include forming the structure 400, an integrated assembly that includes the structure 400, any part described herein of the structure 400, and/or any part described herein of an integrated assembly that includes the structure 400. For example, the method 700 may include forming one or more of the epitaxial structures 440, the nitride layer 445, and/or the void regions 455.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element’s relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

In some implementations, an integrated assembly includes a first semiconductor pillar extending vertically from a substrate; a second semiconductor pillar extending vertically from the substrate; a first epitaxial structure extending vertically from the first semiconductor pillar; a second epitaxial structure extending vertically from the second semiconductor pillar, where the first epitaxial structure is separated from the second epitaxial structure by a gap; and a nitride layer over the first epitaxial structure and the second epitaxial structure, where the nitride layer includes a bridge portion extending between a side portion of the first epitaxial structure and a side portion of the second epitaxial structure.

In some implementations, an integrated assembly includes a first cell contact pillar extending vertically from a substrate; a second cell contact pillar extending vertically from the substrate; a first epitaxial structure extending vertically from an upper surface of the first cell contact pillar; a second epitaxial structure extending vertically from an upper surface of the second cell contact pillar; and a void region between the first epitaxial structure and the second epitaxial structure.

In some implementations, a method includes forming a first semiconductor pillar extending vertically from a substrate; forming a second semiconductor pillar extending vertically from the substrate; forming a first epitaxial structure extending vertically from the first semiconductor pillar and a second epitaxial structure extending vertically from the second semiconductor pillar; and forming a nitride layer over the first epitaxial structure and the second epitaxial structure, where the nitride layer includes a bridge portion extending between a side portion of the first epitaxial structure and a side portion of the second epitaxial structure.

As used herein, the terms “substantially” and “approximately” mean “within reasonable tolerances of manufacturing and measurement.” All ranges described herein are inclusive of numbers at the ends of those ranges, unless specifically indicated otherwise. As used herein, the term “formed” may, depending on the context, refer to a state or a position of a first feature relative to a second feature, and does not imply any specific method or sequence of formation.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a first semiconductor pillar extending vertically from a substrate;
a second semiconductor pillar extending vertically from the substrate;
a first epitaxial structure extending vertically from the first semiconductor pillar;
a second epitaxial structure extending vertically from the second semiconductor pillar, wherein the first epitaxial structure is separated from the second epitaxial structure by a gap; and
a nitride layer over the first epitaxial structure and the second epitaxial structure, wherein the nitride layer comprises a bridge portion extending between a side portion of the first epitaxial structure and a side portion of the second epitaxial structure.

2. The integrated assembly of claim 1, further comprising:
a third semiconductor pillar extending vertically from the substrate; and
a digit line extending in a horizontal direction over the third semiconductor pillar, wherein the digit line comprises a conductive portion and one or more dielectric layers covering one or more sidewalls of the conductive portion.

3. The integrated assembly of claim 2, wherein the one or more dielectric layers comprise a first dielectric material having a first dielectric constant and a second dielectric material having a second dielectric constant different than the first dielectric constant.

4. The integrated assembly of claim 3, wherein the first dielectric material is silicon oxycarbide.

5. The integrated assembly of claim 2, wherein the nitride layer covers a sidewall portion of the digit line.

6. The integrated assembly of claim 2, further comprising:
a bit contact electrically coupling the conductive portion to the third semiconductor pillar.

7. The integrated assembly of claim 1, further comprising:
an access line extending in a horizontal direction, wherein the access line comprises a conductive portion, a cap portion on the conductive portion, and a gate oxide material between the conductive portion and the first semiconductor pillar.

8. The integrated assembly of claim 7, wherein the access line is between the first semiconductor pillar and the second semiconductor pillar.

9. The integrated assembly of claim 7, wherein the first epitaxial structure and the second epitaxial structure are above the access line.

10. The integrated assembly of claim 1, wherein the gap is below the bridge portion of the nitride layer.

11. An integrated assembly, comprising:
a first cell contact pillar extending vertically from a substrate;
a second cell contact pillar extending vertically from the substrate;
a first epitaxial structure extending vertically from an upper surface of the first cell contact pillar;
a second epitaxial structure extending vertically from an upper surface of the second cell contact pillar; and
a void region between the first epitaxial structure and the second epitaxial structure.

12. The integrated assembly of claim 11, wherein the first epitaxial structure has a rounded profile.

13. The integrated assembly of claim 11, further comprising:
a nitride layer over the first epitaxial structure and the second epitaxial structure, wherein the nitride layer comprises a bridge portion extending between a side portion of the first epitaxial structure and a side portion of the second epitaxial structure.

14. The integrated assembly of claim 13, wherein the void region is below the bridge portion of the nitride layer.

15. The integrated assembly of claim 11, further comprising:
a bit contact pillar extending vertically from the substrate; and
a digit line extending in a first horizontal direction over the bit contact pillar, wherein the digit line comprises a conductive portion and one or more dielectric layers covering one or more sidewalls of the conductive portion.

16. A method, comprising:
forming a first semiconductor pillar extending vertically from a substrate;
forming a second semiconductor pillar extending vertically from the substrate;
forming a first epitaxial structure extending vertically from the first semiconductor pillar and a second epitaxial structure extending vertically from the second semiconductor pillar; and
forming a nitride layer over the first epitaxial structure and the second epitaxial structure, wherein the nitride layer comprises a bridge portion extending between a side portion of the first epitaxial structure and a side portion of the second epitaxial structure.

17. The method of claim 16, further comprising:
forming a third semiconductor pillar extending vertically from the substrate; and
forming a digit line extending in a first horizontal direction over the third semiconductor pillar, wherein the digit line comprises a conductive portion and one or more dielectric layers covering one or more sidewalls of the conductive portion.

18. The method of claim 17, wherein forming the digit line comprises:
removing a portion of the one or more dielectric layers to form a trench exposing respective upper surfaces of the first semiconductor pillar and the second semiconductor pillar.

19. The method of claim 16, wherein forming the first epitaxial structure and forming the second epitaxial structure comprises:
performing an epitaxial deposition process to grow first semiconductor material on an upper surface of the first semiconductor pillar and to grow second semiconductor material on an upper surface of the second semiconductor material.

20. The method of claim 16, wherein forming the nitride layer comprises:
depositing nitride material to cover a portion of the first epitaxial structure and to cover a portion of the second epitaxial structure, wherein depositing the nitride material forms a void region, and wherein:
the void region is between the first epitaxial structure and the second epitaxial structure; and
the void region is below the bridge portion of the nitride layer.
